(19) United States
(12) Patent Application Publication
(10) Pub. No.: US 2015/0136029 A1
(43) Pub. Date: May 21, 2015

(54) FILM DEPOSITION SYSTEM

(71) Applicant: Kabushiki Kaisha Kobe Seiko Sho (Kobe Steel, Ltd.), Kobe-shi (JP)

(72) Inventor: Hirofumi FUJII, Takasago-shi (JP)

(73) Assignee: Kabushiki Kaisha Kobe Seiko Sho (Kobe Steel, Ltd.), Kobe-shi (JP)

(21) Appl. No.: 14/521,589

(22) Filed: Oct. 23, 2014

(30) Foreign Application Priority Data
Nov. 18, 2013 (JP) 2013-237859

(51) Int. Cl. C23C 14/50; C23C 14/24

(52) U.S. Cl. CPC C23C 14/505; C23C 14/24; C23C 14/50
USPC 118/730

(57) ABSTRACT

A rotary table unit in a film deposition system according to the present invention includes a rotary table and first interchangeable units and second interchangeable units detachably attachable to the rotary table. A workpiece to be mounted on each second interchangeable unit differs in diameter from a workpiece to be mounted on each first interchangeable unit. To keep constant a distance between each of the workpieces of different sizes and a target, a distance between a position, where the workpiece mounted on each first workpiece mount plate faces an evaporation surface of the target, and a rotation center of the rotary table is set equal to a distance between a position, where the workpiece mounted on each second workpiece mount plate faces the evaporation surface of the target, and the rotation center.

### BACKGROUND OF THE INVENTION

1. Field of the Invention

The present invention relates to a film deposition system for subjecting workpieces to film deposition treatment with particles evaporated from a target.

2. Description of the Related Art

Hitherto, there is known a film deposition system for forming hard films on surfaces of workpieces mounted on a rotary table with particles evaporated from a surface of a target by evaporating the material of the target by vacuum arc discharge, sputtering or the like inside a vacuum chamber.

To maintain the deposition rate and film thickness distribution constant during film deposition, the distance between the target and the surface of each workpiece is preferably constant. That is, a greater distance a raises a problem that the deposition rate is lowered, which a smaller distance causes a problem that the uniformity of the film thickness distribution deteriorates. Taking these problems into consideration, the distance should preferably be constant.

If workpieces to be subjected to film deposition treatment have different sizes, a dedicated rotary table is, therefore, normally provided for every size of workpieces so as to make constant the distance between the target and the surface of each workpiece.

The provision of such a dedicated rotary table for every size of workpieces, however, requires additional equipment cost and a space for storing plural rotary tables.

To solve these problems, there is proposed, as described in Japanese Patent No. 4234652, a workpiece holding apparatus capable of keeping a constant distance between plural workpieces of different sizes and a target despite the use of a single rotary table.

This workpiece holding apparatus includes a non-rotatably fixed central gear; a rotary table that includes an annular guide portion surrounding the central gear on a radially outer side thereof, and arranged concentrically with the central gear; gear units arranged between the central gear and the guide portion; plural spacers detachably provided on the gear units, and having different widths; and plural mount bases provided on the gear units for mounting workpieces thereon.

Each gear unit includes a first planetary gear in meshing engagement with the central gear; a rotational shaft rotatably supporting the first planetary gear; a support member rockably supported on the rotational shaft; a second planetary gear in meshing engagement with the first planetary gear; and a support shaft coupled to the second planetary gear. The rotational shaft is fixed on an upper surface of the rotary table. The support shaft is rotatably supported by the support member. The second planetary gear and the support shaft are, therefore, rockably supported about the rotational shaft for the first planetary gear via the support member.

To an upper end of the support shaft coupled to each second planetary gear, a mount base is coupled. This mount base is rotatable, together with the secondary planetary gear, about an axis thereof. Furthermore, a spacer is detachably attached to the support shaft.

When any one of the spacers comes into contact with the guide portion of the rotary table, the spacer is restricted from moving in a radial direction of the rotary table. Furthermore, contact of any adjacent ones of the spacers restricts the movements of the adjacent spacers in a circumferential direction of the rotary table. As can be seen from the foregoing, each spacer is restricted from moving in the radial direction of the rotary table upon its contact with the guide portion of the rotary table so that a revolution orbit of the support shaft to which the spacer is attached, and the mount base coupled to the support shaft (that is, a revolution orbit around a rotation center of the rotary table) is defined by the size of the spacer.

In the workpiece holding apparatus having the above-described configuration, each first planetary gear which is in meshing engagement with the fixed central gear revolves around the rotation center of the rotary table while rotating about the axis thereof by rotating the rotary table. In addition, the second planetary gear which is in meshing engagement with the first planetary gear and the mount base coupled to the second planetary gear via the support shaft also revolve around the rotation center of the rotary table while rotating about axes thereof. As a result, the workpiece mounted on each mount base can revolve around the rotation center of the rotary table while rotating on an axis thereof. As a consequence, it is possible to subject the workpieces to film deposition treatment with particles evaporated from a target disposed outside of the revolution orbit of the workpieces.

Moreover, it is possible to keep constant the radii of the revolution orbits of workpieces mounted on the plural mount bases by changing the mount bases and the spacers to those corresponding to the size of the workpieces. This can keep constant the distance between the target and each workpiece.

### SUMMARY OF THE INVENTION

The workpiece holding apparatus disclosed in Japanese Patent No. 4234652 includes plural spacers for keeping constant the revolution orbits of the support shafts for supporting the mount bases and plural mount bases for mounting workpieces thereon. These spacers not only come into contact with on the guide portion of the rotary table but also come into contact between adjacent ones thereof.

While film deposition treatment is conducted the internal temperature of the vacuum chamber of the film deposition system becomes quite high because the particles evaporated from the surface of the target have high energy. These spacers thermally expand, accordingly. However, if any spacer comes into contact with the guide portion of the rotary table and any adjacent ones of the spacers also come into contact with each other as described above, it is no longer possible to absorb dimensional changes caused by thermal expansions of the spacers, resulting in a potential problem that the gear units may not be able to operate normally. This may, therefore, lead to another potential problem that the mount bases with the workpieces mounted thereon may hardly rotate or revolve.

The present invention has been made in view of such circumstances as described above, and an object of the present invention is to provide a film deposition system capable of keeping a constant distance between workpieces of different sizes and a target while achieving the rotation and revolution of the workpieces.

To attain the above-described object, a film deposition system according to one aspect of the present invention is a film deposition system for subjecting workpieces to film deposition treatment with particles evaporated from a target, including: a chamber with the target placed therein, and a rotor unit accommodated in the chamber; wherein the rotor unit includes a rotor; a drive unit for driving the rotor to rotate about a rotation center; and plural interchangeable units including workpiece mount plates for mounting thereon the workpieces, respectively, and support members rotatably supporting the workpiece mount plates, respectively. The plural interchangeable units are detachably attachable to the rotor such that the interchangeable units are arranged apart from one another and side by side at intervals in a circumferential direction of the rotor.

With this configuration, the interchangeable units are detachably attached to the rotor so that the interchangeable units of various dimensions can be selectively attached to the rotor. It is, therefore, possible to keep seizes constant distance between workpieces of different sizes and a target by selecting interchangeable units, each of which includes a support member of a length corresponding to the size of the workpiece to be mounted on a workpiece mount plate, and detachably attaching the selected interchangeable units to the rotor.

Furthermore, upon detachably attaching plural interchangeable units to the rotor, the interchangeable units are attached to the rotor such that they are arranged with intervals in the circumferential direction of the rotor. Owing to this, the interchangeable units are not in contact with each other. As a result, even if these interchangeable units thermally expand during film deposition treatment, the individual interchangeable units can absorb their own dimensional changes occurred by the thermal expansion so that the thermal expansion does not affect the rotation and revolution of the workpieces.

Preferably, the interchangeable units may include plural first interchangeable units including first workpiece mount plates for mounting thereon plural workpieces of a first diameter, respectively, and first support members rotatably supporting the first workpiece mount plates, respectively, the plural first interchangeable units may be detachably attachable to the rotor such that the first interchangeable units are arranged apart from one another and side by side at intervals in the circumferential direction of the rotor; and plural second interchangeable units may include second workpiece mount plates for mounting thereon plural workpieces of a second diameter larger than the first diameter, respectively, and second support members rotatably supporting the second workpiece mount plates, respectively, the plural second interchangeable units may be detachably attachable to the rotor such that the second interchangeable units are arranged apart from one another and side by side at intervals in the circumferential direction of the rotor, and that at least one type of interchangeable units selected from the group constituting of the first interchangeable units and the second interchangeable units may be selectable for attachment to the rotor.

With this configuration, the film deposition system includes the first interchangeable units and the second interchangeable units including the workpiece mount plates corresponding to the workpieces of different sizes, that is, the first workpiece mount plates and the second workpiece mount plates, respectively. It is, therefore, possible to interchangeable the first and second interchangeable units depending on the sizes of workpieces. By selecting one type of interchangeable units from the first or second interchangeable units and detachably attaching the selected interchangeable units to the rotor, it is possible to keep a constant distance between the workpieces of the different sizes and the target.

A distance between a position, where the workpiece mounted on each first workpiece mount plate faces an evaporation surface of the target from which the particles are evaporated, and the rotation center of the rotor may preferably be set equal to a distance between a position, where the workpiece mounted on each second workpiece mount plate faces the evaporation surface, and the rotation center of the rotor.

With this configuration, the distance between the target and the workpiece mounted on the first workpiece mount plate of each of the first interchangeable units is equal to that between the target and the workpiece mounted on the second workpiece mount plate of each of the second interchangeable units. A constant distance can, therefore, be maintained between the workpieces of the different sizes and the target.

Moreover, preferably, the target may be arranged on a radial by outer side of the rotor, and a radius of a circumscribed circle, with which the plural workpieces mounted, respectively, on the plural first workpiece mount plates arranged side by side in the circumferential direction of the rotor, are in contact, respectively, on the radially outer side of the rotor may be set equal to a radius of a circumscribed circle, with which the plural workpieces mounted, respectively on the plural second workpiece mount plates arranged side by side in the circumferential direction of the rotor, are in contact, respectively, on the radially outer side, of the rotor.

If the target is arranged on a radially outer side of the rotor, the distance from the rotation center of the rotor to an evaporation surface of the target is constant. By setting equal the radii of circumscribed circles of plural workpieces mounted on the first workpiece mount plates and the second workpiece mount plates as described above, the distances obtained by subtracting the radii of these circumscribed circles between the distance from the rotation center of the rotor and the evaporation surface of the target, respectively, that is, the distances between the target and the workpieces mounted on the respective workpiece mount plates of the first interchangeable units and the second interchangeable units become equal to each other.

Furthermore, preferably, the target may be arranged on a central axis of the rotor, and a radius of an inscribed circle, with which the plural workpieces mounted, respectively, on the plural first workpiece mount plates, arranged side by side in the circumferential direction of the rotor, are in contact, respectively, on a radially inner side of the rotor may be set equal to a radius of an inscribed circle, with which the plural workpieces mounted, respectively, on the plural second workpiece mount plates, arranged side by side in the circumferential direction of the rotor, are in contact, respectively, on the radially inner side of the rotor.

If the target is arranged at a rotation center on a radially inner side of the rotor, the distance from the rotation center of the rotor to the evaporation surface of the target is constant. Therefore, as described above, by setting equal the radii of the inscribed circles of plural workpieces mounted on the first workpiece mount plates and the second workpiece mount plates, the distances obtained by subtracting the distance between the rotation center of the rotor and the evaporation surface of the target from the radii of these inscribed circles, that is, the distances between the target and the workpieces mounted on the respective workpiece mount plates of the first interchangeable units and the second interchangeable units become equal to each other.

Preferably, the rotor may include plural first attachment portions to which the first interchangeable units are attachable; and plural second attachment portions to which the second interchangeable units are attachable, the plural first attachment portions may be included as many as a maximum attachable number of the first interchangeable units, and may be disposed at equal intervals such that the plural first attachment portions are arranged side by side in the circumferential direction of the rotor, and the plural second attachment portions may be included as many as a maximum attachable number of the second interchangeable units, and may be disposed at equal intervals such that the plural second attachment portions are arranged side by side in the circumferential direction of the rotor.

With this configuration, even if the number of the first interchangeable units differs from that of the second interchangeable units, the attachment the first interchangeable units and the second interchangeable units to the corresponding first attachment portions and second attachment portions on the rotor makes it possible to easily dispose the interchangeable units at equal intervals such that they are arranged side by side in the circumferential direction of the rotor.

Moreover, the first plural attachment portions and the second plural attachment portions may preferably be partly in common with each other.

With this configuration, it is possible to decrease the total number of the first attachment portions and the second attachment portions, and to improve the freedom of arrangement of the first attachment portions and the second attachment portions on the surface of the rotor and that of their peripheral members.

Furthermore, preferably, the rotor unit may further include a base that rotatably supports the rotor; and a fixed gear fixed on the base; the first interchangeable units may each further include a first planetary gear, which is coaxially coupled to the first workpiece mount plate and is rotatable about an axis thereof in meshing engagement with the fixed gear the second interchangeable units may each further include a second planetary gear, which is coaxially coupled to the second workpiece mount plate and is rotatable about an axis thereof in meshing engagement with the fixed gear; each first support member may be a first arm that includes a rotation support member rotatably supporting the first workpiece mount plate and the first planetary gear thereon, and a first couple portion detachably coupled to the rotor, and that revolves, together with the rotor, around the rotation center; and each second support member may be a second arm that includes a rotation support member rotatably supporting the second workpiece mount plate and the second planetary gear thereon, and a second couple portion detachably coupled to the rotor, and that revolves, together with the rotor, around the rotation center.

With this configuration, if either the first interchangeable units or the second interchangeable unit are attached to the rotor, the first (or second) workpiece mount plates of these first (or second) interchangeable units revolve around the rotation center of the rotor while being supported on the respective first (or second) arms. In addition, the first (or second) planetary gears rotate about the axes thereof in meshing engagement with the fixed gear, whereby these first (or second) workpiece mount plates rotate about the axes thereof. Using drive force that can rotate the rotor, the first (or second) workpiece mount plates can rotate about the axes thereof.

Moreover, preferably, the rotor unit may further include a base that rotatably supports the rotor; and a fixed gear fixed on the base, the first interchangeable units may further include plural the first workpiece mount plates and plural first planetary gears that are coaxially coupled to the plural first workpiece mount plates, respectively, and that are rotatable about axes thereof in meshing engagement with the fixed gear the second interchangeable units may further include plural second workpiece mount plates and plural second planetary gears that are coaxially coupled to the plural second workpiece mount plates, respectively, and that are rotatable about axes thereof in meshing engagement with the fixed gear; the first support members may be first attachment plates that include plural rotation support members rotatably supporting the plural first workpiece mount plates and the plural first planetary gears thereon, and first couple portions coupled to the rotor, and that revolve, together with the rotor, around the rotation center, and the second support members may be second attachment plates that include plural rotation support members rotatably supporting the plural second workpiece mount plates and the plural second planetary gears thereon, and second couple portion coupled to the rotor, and may revolve, together with the rotor, around the rotation center.

With this configuration, the first interchangeable units and the second interchangeable units each include the attachment plate including plural rotation support members that rotatably support the plural second workpiece mount plates and the plural second planetary gears. Owing to this, the number of interchangeable units can be decreased while securing workpiece mount plates as many as needed. This can, accordingly, reduce the man-hours of work for the attachment and detachment of interchangeable units, and moreover, facilitate the management of interchangeable units.

Furthermore, preferably, the fixed gear may be an internal gear having teeth on a side of an inner circumference thereof, and the fixed gear may be located on a side radially outer than the first planetary gears and the second planetary gears, and may be in meshing engagement with the first planetary gears and the second planetary gears.

With this configuration, it is possible to arrange the fixed gear on radially outer side apart from the rotor and to secure a space around the rotation center of the rotor. The designing and manufacture of the rotor unit can be facilitated accordingly.

Moreover, diameters of the first planetary gears and the second planetary gears may preferably be set based on diameters of the first workpiece mount plates and the second workpiece mount plates, respectively.

The present invention requires, as a premise, the configuration that the diameter of the first workpiece mount plate of each of the first interchangeable units differs from that of the second workpiece mount plate of each of the second interchangeable units. In such a case, the distance between the rotation center of each of the first workpiece mount plates and the first corresponding planetary gear coaxially coupled to the first workpiece mount plate and the teeth of the fixed gear differs from that between the rotation center of each of the second workpiece mount plates and the corresponding second planetary gear coaxially coupled to the second workpiece mount plate and the teeth of the fixed gear. Therefore, by setting the diameters of the first planetary gear and the second planetary gear based on the diameters of the first workpiece mount plate and the second workpiece mount plate, respectively, as described above, it is possible to set the first planetary gear and the second planetary gear in such dimensions that the first planetary gear and the second planetary gear are assured to brought into meshing engagement with the fixed gear even if the distances between their rotation centers and the teeth of the fixed gear differ.

As has been described above, the film deposition system according to the present invention can keep a constant distance between workpieces of the different sizes and a target while achieving the revolution and rotation of the workpieces.

### BRIEF DESCRIPTION OF THE DRAWINGS

FIG. 1 is a plan view illustrating an internal configuration of a when twelve (12) first interchangeable units have been attached in a film deposition system according to an embodiment of the present invention;

FIG. 2 is a longitudinal sectional view of the film deposition system of FIG. 1;

FIG. 3 is a plan view of a rotor of FIG. 1;

FIG. 4 is a plan view showing the internal configuration of the chamber when nine (9) second interchangeable units have been attached in the film deposition system of FIG. 1;

FIG. 5 is a longitudinal sectional view of the film deposition system of FIG. 4;

FIG. 6 is a plan view of a modification of the embodiment according to the present invention, in which three first interchangeable units, each including four workpiece mount plates, are attached to the rotor;

FIG. 7 is a plan view of the modification of the embodiment according to the present invention, in which three second interchangeable units, each including three workpiece mount plates, are attached to the rotor;

FIGS. 8A and 8B are plan views of another modification of the embodiment according to the present invention that includes an internal gear as a fixed gear, in which twelve (12) first interchangeable units are attached in FIG. 8A and nine (9) second interchangeable units are attached in FIG. 8B. However, support members (arms) are omitted in both figures according to another modification the present invention;

FIGS. 9A and 9B are plan views of a further modification of the embodiment according to the present invention that a target is arranged at a rotation center on a radially inner side of the rotor, in which twelve (12) first interchangeable units are attached in FIG. 9A and nine (9) second interchangeable units are attached in FIG. 9B. However, support members (arms) are omitted in both figures; and

FIGS. 10A, 10B, and 10C are a plan view illustrating a positional relation between a reference table unit including twelve (12) workpiece mount plates and the target, a plan view illustrating a state in which larger-diameter workpieces are mounted on every other workpiece mount plate of the reference table unit of FIG. 10A, and a plan view illustrating a positional relation between a dedicated table unit for mounting the larger-diameter workpieces and the target, all as comparative examples of the present invention, respectively.

### DESCRIPTION OF THE PREFERRED EMBODIMENTS

Hereinafter, a film deposition system 1 according to an embodiment of the present invention will be described in further detail with reference to the drawings.

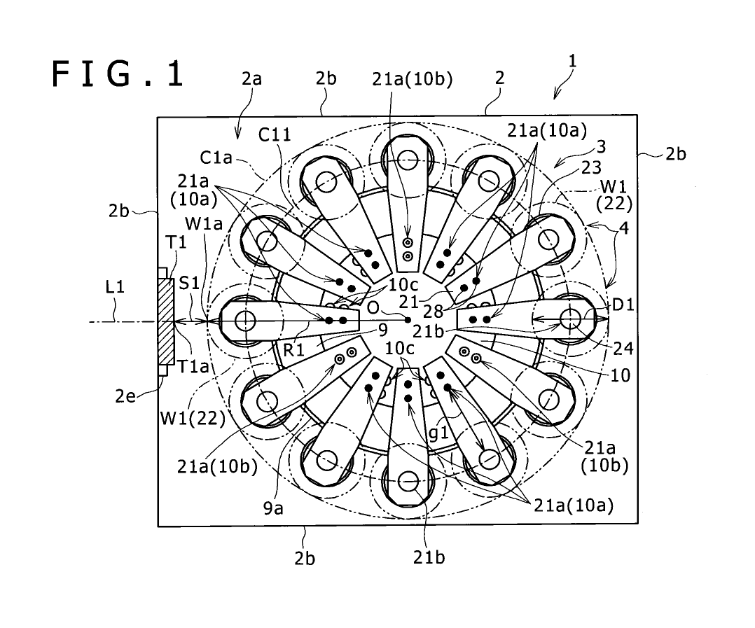

The film deposition system 1 shown in FIGS. 1 to 5 is a system which by interchanging two types of interchangeable units 4, 30, can subject workpieces W1, W2 of different diameters to film deposition treatment with particles evaporated from a target T1 while causing the workpieces to rotate and to revolve.

While workpieces of various shapes can be used as the workpieces W1, W2, cylindrical members are adopted in this embodiment for the ease of understanding the invention. Any workpieces can be adopted as the workpieces W1, W2 in so far as they have shapes and sizes mountable on first and second workpiece mount plates 22, 32 to be described subsequently herein, respectively, and examples of the workpieces in the present invention may include not only a cylindrical member to be arranged on each workpiece mount plate but also plural linear members such as drills to be arranged upright thereon and multiple small-sizes tool components to be arranged thereon.

This film deposition system 1 includes a chamber 2 and a rotary table unit 3 accommodated inside the chamber 2.

The chamber 2 is constituted by a hollow casing, and includes four sidewalls 2b, a bottom wall 2c, and a top wall (not shown) located above and facing the bottom wall 2c. These walls define a space 2a in which the workpieces W1 and W2 are placed and are subjected to film deposition treatment.

The chamber 2 also includes a target holding portion 2e for holding the target T1 thereon. The target holding portion 2e is attached to an inner surface of one of the sidewalls 2b, and is arranged on a radially outer side of a rotary table 10.

One of the sidewalls 2b of the chamber 2 can be freely opened/closed, through which the rotary table unit 3 can be installed in or uninstalled from the chamber 2.

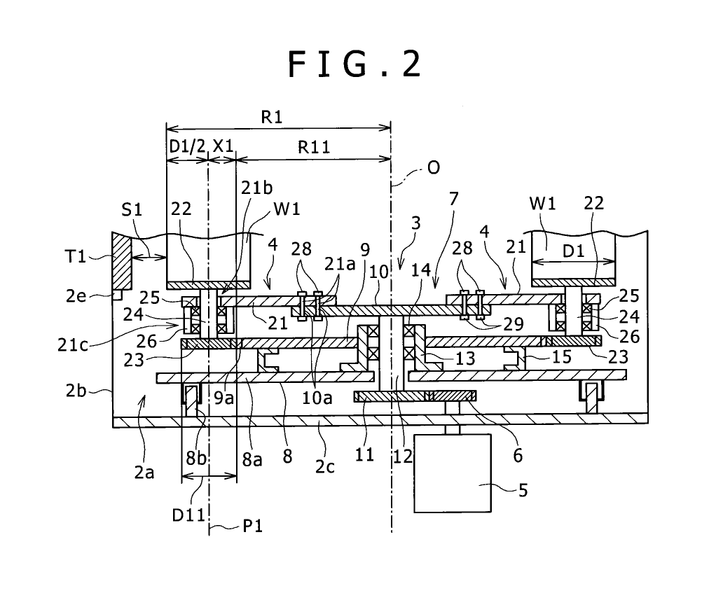

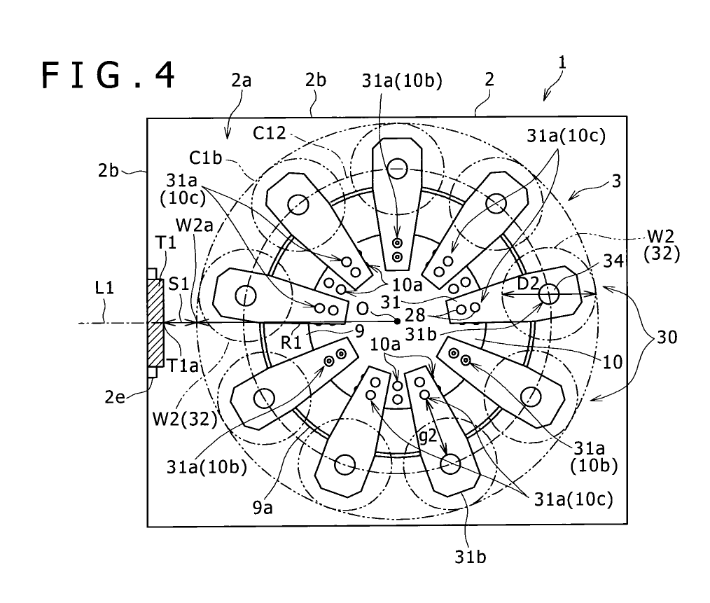

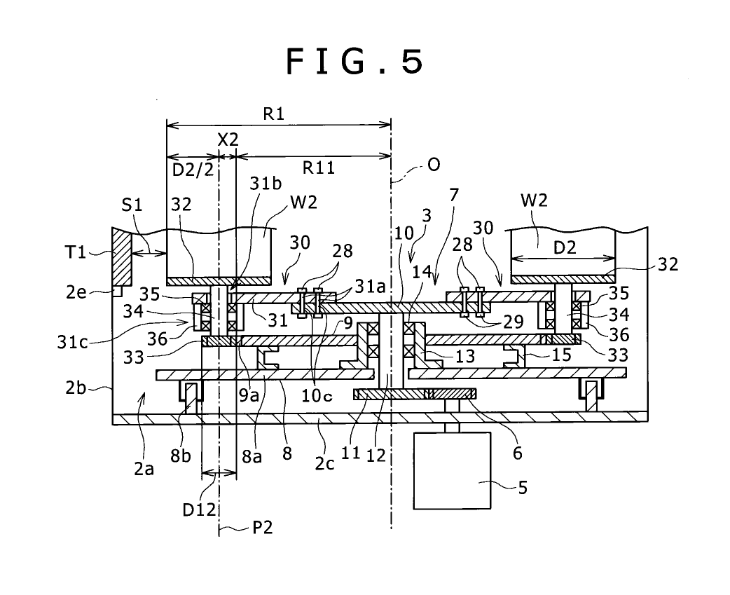

The rotary table unit 3 includes a rotary table unit main body 7 having the rotary table 10, and two types of interchangeable units detachably attachable to the rotary table 10, that is, plural (as many as 12) first interchangeable units 4 and plural (as many as 9) second interchangeable units 30. One type of interchangeable units, that is, the first interchangeable units 4 shown in FIGS. 1 and 2 or the second interchangeable units 30 shown in FIGS. 4 and 5 are selected and attached to the rotary table 10.

The rotary table unit main body 7 includes the rotary table 10 as a rotor, a revolution gear 11, a rotational shaft 12 coupling the rotary table 10 and the revolution gear 11 to each other, a truck 8 (base) rotatably supporting the rotational shaft 12 of the rotor, and a fixed gear 9 fixed on the truck 8.

The truck 8 includes a table base 8a and plural wheels 8b attached to a lower portion of the table base 8a. By using this truck 8, the rotary table unit 3 can be freely moved between an inside and an outside of the chamber 2.

The fixed gear 9 that extends horizontally via an annular fixed base 15 is fixed on an upper surface of the table base 8a. The fixed gear 9 is an external gear having many gear teeth 9a on an outer circumference thereof.

The rotational shaft 12 that extends vertically is coupled to a center of a lower surface of the rotary table 10. The rotational shaft 12 is rotatably supported by bearings 14 inside a fixed cylinder 13 provided on the upper surface of the table base 8a. A lower end of the rotational shaft 12 extends to below the table base 8a through the table base 8a, and is coupled to a rotation center of the revolution gear 11. The rotary table 10 and the revolution gear 11 can, therefore, revolve around a rotation center O of the rotational shaft 12.

In a state in which the rotary table unit 3 is arranged at a predetermined position inside the chamber 2, the revolution gear 11 is in meshing engagement with a drive gear 6 arranged above the bottom wall 2c of the chamber 2. The drive gear 6 is coupled to a rotational shaft of a drive motor 5 installed below the bottom wall 2c of the chamber 2. The revolution gear 11, the drive gear 6, and the drive motor 5 constitute a drive unit that drives the rotary table 10 to rotate.

As shown in FIGS. 1 to 5, the rotary table 10 includes through-holes 10a dedicated for the first interchangeable units and permitting the attachment of the first interchangeable units 4, through-holes 10b commonly usable for the first and second interchangeable units for the selective attachment of either the first interchangeable units 4 or the second interchangeable units 30, and through-holes 10c dedicated for the second interchangeable units and permitting the attachment of the second interchangeable units 30.

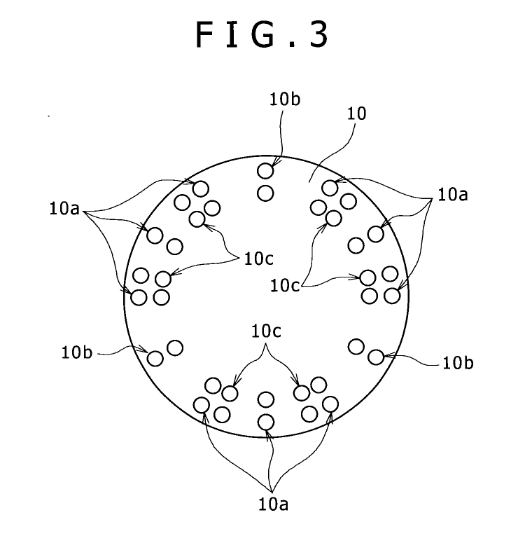

As shown in FIG. 3, the through-holes 10b which are commonly usable for the first and second interchangeable units are formed in pairs at three locations apart from one another around a rotation center O of the rotary table 10 at intervals of 120 degrees in a circumferential direction. On the other hand, the through-holes 10a are formed around the rotation center O at intervals of 30 degrees in the circumferential direction and between the paired through-holes 10b provided at the intervals of 120 degrees, and are formed in pairs at nine locations in total. Moreover, the through-holes 10c are formed around the rotation center O at intervals of 40 degrees in the circumferential direction and between the paired through-holes 10b provided at the intervals of 120 degrees, and are formed in pairs at six locations in total.

Therefore, the through-holes 10a at the nine locations and the through-holes 10b at the three locations constitute plural (12) first attachment portions to which plural (12) first interchangeable units 4 are attached, respectively. In other words, the first attachment portions (that is, the through-holes 10a and 10b) are included as many as corresponding to the number (12) of the first interchangeable units 4, and are arranged side by side at equal intervals in the circumferential direction of the rotary table 10.

Furthermore, the through-holes 10b at the three locations and the through-holes 10c at the six locations constitute plural (nine) second attachment portions to which plural (nine) second interchangeable units 30 are attached, respectively. Therefore, the second attachment portions (that is, the through-holes 10b and 10c) are included as many as corresponding to the number (nine) of the second interchangeable units 30, and are arranged side by side at equal intervals in the circumferential direction of the rotary table 10.

As described above, the plural first attachment portions (through-holes 10a and 10b) and the plural second attachment portions (through-holes 10b and 10c) use the through-holes 10b in common.

As shown in FIGS. 1 and 2, the 12 first interchangeable units 4 are detachably attached to the respective first attachment portions (through-holes 10a and 10b) of the rotary table 10 such that they are arranged apart from one another and side by side at equal intervals in the circumferential direction of the rotary table 10.

Each first interchangeable unit 4 includes a first workpiece mount plate 22 as a rotor a first planetary gear 23, a rotational shaft 24 integrally coupling the first workpiece mount plate 22 and the first planetary gear 23 to each other, and a first arm 21 as a first support member that supports the rotational shaft 24 for the rotor rotatably (about an axis thereof).

The first workpiece mount plate 22 is a disc member of a diameter D1 equal to that of each workpiece W1, and the workpiece W1 of the first diameter D1 is mounted on the first workpiece mount plate 22. While an outer circumferential surface of the first workpiece mount plate 22 is in registration with that of the workpiece W1 in this embodiment, the outer circumferential surfaces are not necessarily in registration with each other. The first workpiece mount plate 22 is arranged above a through-hole 21b formed in an end of the first arm 21. The vertically-extending rotational shaft 24 is coupled to a center of a lower surface of the first workpiece mount plate 22. The rotational shaft 24 extends through the through-hole 21b of the first arm 21 to below of the first arm 21 and is rotatably supported by a rotation support member 21c to be described subsequently herein. A lower end of the rotational shaft 24 is coupled to a rotation center of the first planetary gear 23. The first workpiece mount plate 22 and the first planetary gear 23 can, therefore, rotate about a rotation center P1 of the rotational shaft 24. The rotation centers P1 of the rotational shafts 24 of the respective first interchangeable units 4 are arranged side by side at equal intervals on a virtual circle C11 shown in FIG. 1.

The first planetary gear 23 is arranged below the through-hole 21b of the first arm 21, and is coaxially coupled to the first workpiece mount plate 22 by the above-described rotational shaft 24. The first planetary gear 23 is in meshing engagement with the fixed gear 9.

Two through-holes 21a (first coupled portions) to be detachably coupled to the rotary table 10 are formed in one end of the first arm 21, and the through-hole 21b through which the rotational shaft 24 that couples the first workpiece mount plate 22 and the first planetary gear 23 to each other extends is formed in the other end of the first arm 21.

The through-holes 21a of the first arm 21 are superimposed on the through-holes 10a, 10b constituting a first attachment portion, and bolts 28 are inserted extending vertically through these through-holes 21a, 10a, 10b. Nuts 29 are fastened to end portions of the respective bolts 28, whereby the first interchangeable unit 4 is detachably attached to the first attachment portion (that is, through-holes 10a, 10b) of the rotary table 10 and can revolve, together with the rotary table 10, around the rotation center O.

The rotational shaft 24 can extend through the through-hole 21b. The first arm 21 also includes, at a portion around the through-hole 21b on a lower surface of the first arm 21, the rotation support member 21c that rotatably supports the first workpiece mount plate 22 and the first planetary gear 23.

The rotation support member 21c includes a fixed cylinder 26 fixed to the other end of the first arm 21, and bearings 25 arranged inside the fixed cylinder 26 and rotatably supporting the rotational shaft 24 that couples the first workpiece mount plate 22 and the first planetary gear 23 to each other.

As shown in FIGS. 4 and 5, the nine second interchangeable units 30, on the other hand, are detachably attached to the respective second attachment portions (through-holes 10b and 10c) of the rotary table 10 such that they are arranged apart from one another and side by side at equal intervals in the circumferential direction of the rotary table 10.

Similarly to each first interchangeable unit 4 described above, each second interchangeable unit 30 includes a second workpiece mount plate 32 as a rotor, a second planetary gear 33, a rotational shaft 34 integrally coupling the second workpiece mount plate 32 and the second planetary gear 33 to each other, and a second arm 31 as a second support member that supports the rotational shaft 34 for the rotor rotatably (about an axis thereof).

The second workpiece mount plate 32 is a disc member of a diameter D2 larger than that of the first workpiece mount plate 22, and the workpiece W2 of the second diameter D2 larger than the first diameter D1 is mounted on the second workpiece mount plate 32. An outer circumferential surface of the second workpiece mount plate 32 is in registration with that of the workpiece W2 in this embodiment. The second workpiece mount plate 32 is arranged above a through-hole 31b formed in an end of the second arm 31. The vertically-extending rotational shaft 34 is coupled to a center of a lower surface of the second workpiece mount plate 32. The rotational shaft 34 extends through the through-hole 31b of the second arm 31 to below the second arm 31 and is rotatably supported by a rotation support member 31c to be described subsequently herein. A lower end of the rotational shaft 34 is coupled to a rotation center of the second planetary gear 33. The second workpiece mount plate 32 and the second planetary gear 33 can, therefore, rotate about a rotation center P2 of the rotational shaft 34. The rotation centers P2 of the rotational shafts 34 of the respective second interchangeable units 30 are arranged side by side at equal intervals on a virtual circle C12 shown in FIG. 4.

The second planetary gear 33 is arranged below the through-hole 31b of the second arm 31, and is coaxially coupled to the second workpiece mount plate 32 by the above-described rotational shaft 34. The second planetary gear 33 is in meshing engagement with the second gear 9.

Two through-holes 31a (second coupled portions) to be detachably coupled to the rotary table 10 are formed in one end of the second arm 31, and the through-hole 31b through which the rotational shaft 34 that couples the second workpiece mount plate 32 and the second planetary gear 33 to each other extends is formed in the other end of the second arm 31.

The through-holes 31a of the second arm 31 are superimposed on the through-holes 10b, 10c constituting a second attachment portion, and the bolts 28 are inserted extending vertically through these through-holes 31a, 10b, 10c. The nuts 29 are fastened to end portions of the respective bolts 28, whereby the second interchangeable unit 30 is detachably attached to the second attachment portion (that is, through-holes 10b, 10c) of the rotary table 10 and can revolve, together with the rotary table 10, around the rotation center O.

The rotational shaft 34 can extend through the through-hole 31b. The second arm 31 also includes, at a portion around the through-hole 31b on a lower surface of the second arm 21, the rotation support member 31c that rotatably supports the second workpiece mount plate 32 and the second planetary gear 33.

The rotation support member 31c includes a fixed cylinder 36 fixed to the other end of the second arm 31, and bearings 35 arranged inside the fixed cylinder 36 and rotatably supporting the rotational shaft 34 that couples the second workpiece mount plate 32 and the second planetary gear 33 to each other.

As shown in FIGS. 1 and 4, the lengths of the first arm 21 and the second arm 31 (particularly intervals g1, g2 between the through-holes formed in both of the ends of the first arm 21 and the second arm 31 (described specifically, between the radially outer through-hole 21a and the through-hole 21b and between the radially outer through-hole 31a and the through-hole 31b) are set such that distances between the workpieces W1, W2 and the target T1 are equally S1.

That is, the lengths of the first arm 21 and the second arm 31 are set such that on a line L1 extending through the rotation center O of the rotary table 10 and crossing at right angles to an evaporation surface T1a of the target T1 from which particles are evaporated, a distance (S1 in FIGS. 1 and 2) between a position W1a, where the workpiece W1 mounted on each first workpiece mount plate 22 faces the evaporation surface T1a, and the evaporation surface T1a becomes equal to a distance (S1 in FIGS. 4 and 5) between a position W2a, where the workpiece W2 mounted on each second workpiece mount plate 32 faces the evaporation surface T1a, and the evaporation surface T1a.

In other words, as shown in FIGS. 1 and 2 and FIGS. 4 and 5, with the above-described configuration in which the target T1 is arranged on the radially outer side of the rotary table 10, a radius (R1 in FIG. 1) of a circumscribed circle C1a, with which the workpieces W1 mounted on the respective first workpiece mount plates 22 arranged side by side in the circumferential direction of the rotary table 10, are in contact on the radially outer side of the rotary table 10 is set equal to a radius (R1 in FIG. 4) of a circumscribed circle C1b, with which the workpieces W2 mounted on the respective second workpiece mount plates 32 arranged side by side in the circumferential direction of the rotary table 10, are in contact on the radially outer side of the rotary table 10.

By so setting, as shown in FIGS. 1 and 2 and FIGS. 4 and 5, it is possible, despite the difference in side between the workpieces W1 and W2, to keep constant the distance S1 between the target T1 and each of the workpieces W1 and W2 by interchanging the first interchangeable units 4 and the second interchangeable units 30.

As shown in FIGS. 2 and 5, the diameter D1 of the first workpiece mount plate 22 differs from the diameter D2 of the second workpiece mount plate 32. Because of this, distances X1 and X2 between the rotation centers P1, P2 of the rotational shafts 24 and 34 of these workpiece mount plates 22 and 32 and an outer circumferential surface of the fixed gear 9 differ if the distance S1 between the target T1 and the workpiece W1 or W2 is kept constant. It is necessary to also set the respective diameters D11, D12 of the first planetary gear 23 and the second planetary gear 33, accordingly.

Therefore, the respective diameters D1, D2 of the first planetary gear 23 and the second planetary gear 33 are set based on the respective diameters D1, D2 of the first workpiece mount plate 22 and the second workpiece mount plate 32.

For example, as shown in FIGS. 1 and 2, if the target T1 is located on the radially outer side of the rotary table 10 and the first planetary gear 23 is brought into meshing engagement with the fixed gear 9 as an external gear, the distance X1 between the rotation center P1 of the first workpiece mount plate 22 and first planetary gear 23 and the fixed gear 9 (to be precise, a pitch circle of the fixed gear 9, which will apply equally herein) in the first interchangeable unit 4 is represented by the following Equation (1).

X1=R1−R11−(D1/2) (1)

### Where:

R1: radius of the circumscribed circle C1a with which plural the workpieces W1 are in contact, respectively, on the radially outer side of the rotary table 10;

R11: radius of the fixed gear 9; and

D1: diameter of the first workpiece mount plate 22.

Since the distance X1 is equal to the radius of the first planetary gear 23, the diameter D11 of the first planetary gear 23 is determined as represented by the following Equation (2).

D11=2×X1=2×(R1−R11−(D1/2)) (2)

Likewise, the distance X2 between the rotation center P2 of the second workpiece mount plate 32 and the second planetary gear 33 and the fixed gear 9 in the second interchangeable unit 30 shown in FIGS. 4 and 5 is represented by the following Equation (3).

X2=R1−R11−(D2/2) (3)

### Where:

D2: the diameter of the second workpiece mount plate 32.

Therefore, the diameter D12 of the second planetary gear 33 is determined as represented by the following Equation (4).

D12=2×X2=2×(R1−R11−(D2/2)) (4)

In this way, the respective diameters D11 and D12 of the first planetary gear 23 and the second planetary gear 33 can be set using the respective diameters D1 and D12 of the first workpiece mount plate 22 and the second workpiece mount plate 32.

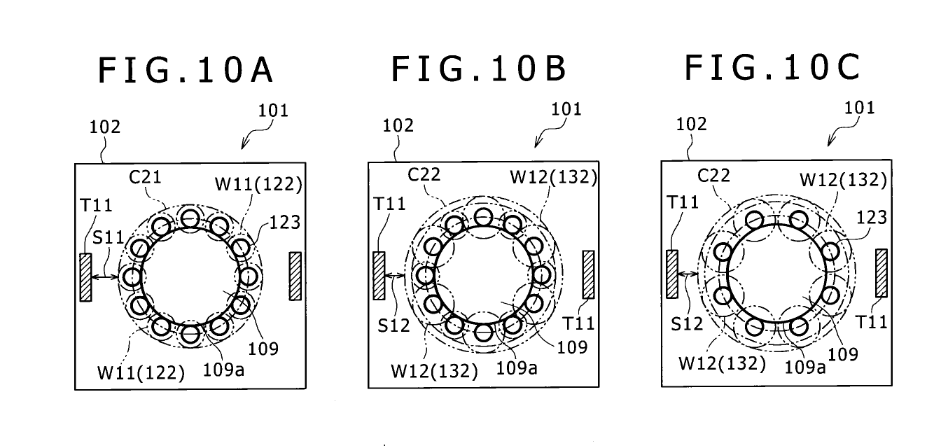

As comparative examples of the present invention, a description will be made about examples in which the distances between workpieces W11, W12 and a target T11 shown in FIGS. 10A to 10C are not constant, in other words, equal.

In a film deposition system 101 shown in FIG. 10A, as one of the comparative examples of the present invention, the workpieces W11 of a predetermined diameter are mounted on 12 workpiece mount plates 122, respectively. The target T11 is arranged on a sidewall of a chamber 102 on a radially outer side of a fixed gear 109 and a rotary table (not shown) arranged coaxially with the fixed gear 109. A planetary gear 123 is coaxially coupled to each workpiece mount plate 122. This planetary gear 123 is in meshing engagement with teeth 109a on an outer circumference of the fixed gear 109. In the arrangement of the 12 workpieces W11 shown in FIG. 10A, a distance between each workpiece W11 and the target T11 is S11.

On the other hand, as shown in FIG. 10B, if the workpiece W12 larger than the workpiece W11 shown in FIG. 10A is mounted on a workpiece mount plate 132 corresponding to a position of each of the workpiece mount plates 122 shown in FIG. 10A, it is conceivable to mount the larger workpieces W12 on the workpiece mount plates 132 arranged every other planetary gear 123 of the 12 planetary gear 123. In this case, however, a distance S12 between each workpiece W12 and the target T11 is smaller than the distance S11 between the workpiece W11 and the target T11 as described above as a result of the change to the larger workpieces W12. As a consequence, the uniformity in film thickness distribution deteriorates. Furthermore, if the larger workpieces W12 are arranged every other workpiece mount plate 122, wider gaps are formed between the workpieces W12, leading to a problem that the efficiency of production is reduced.

Moreover, as shown in FIG. 10C, it is possible to make narrower the gaps between the workpieces W12 by decreasing the number of planetary gears 123 and arranging the workpiece mount plates 132, which are dedicated to the larger workpieces W12, such that they are coaxially coupled to the respective planetary gears 123. However, the distance S12 between each workpiece W12 and the target T11 still remains smaller than the distance S11 between the workpiece W11 and the target T11. Because of this, the problem of the deterioration of the uniformity in film thickness distribution is not solved.

In the film deposition system 1 of the above-described embodiment as shown in FIGS. 1 to 5, it is possible, by contrast, to keep constant the distance S1 between each of the workpieces W1, W2 and the target T11 despite the difference in size between the workpieces W1 and W2 by interchanging the interchangeable units 4 and 30 without changing one rotary table 10 and the rotary table unit main body 7 that includes the rotary table 10.

### (Features)

(1)

In the film deposition system of this embodiment, the first and second interchangeable units 4, 30 are detachably attached to the rotary table 10, so that the interchangeable units of different dimensions can be selectively attached to the rotary table 10. It is, therefore, possible to keep constant the distance between each of the workpieces W1 and W2 of different sizes and the target T1 by selecting the interchangeable units 4 or 30, which include the first or second arms (support members) 21 or 31 of the length corresponding to the size of the workpieces to be mounted on the workpiece mount plates and detachably attaching the selected interchangeable units to the rotary table 10.

Specifically, the film deposition system 1 of this embodiment includes the first interchangeable units 4 and the second interchangeable units 30 including the workpiece mount plates corresponding to the workpieces W1, W2 of the different sizes, that is, the first workpiece mount plates 22 and the second workpiece mount plates 32, respectively. It is, therefore, possible to interchange the first and second interchangeable units 4 and 30 depending on the sizes of the workpieces. By selecting one type of interchangeable units from the first and second interchangeable units 4, 30 and detachably attaching the selected interchangeable units to the rotary table 10, it is possible to keep constant the distance between each of the workpieces W1 and W2 of the different sizes and the target T1.

Furthermore, if one type of interchangeable units are selected from the first interchangeable units 4 and the second interchangeable units 30 are selected and detachably attached to the rotary table 10, the selected interchangeable units are attached to the rotary table 10 such that they are arranged apart from one another and side by side in the circumferential direction of the rotary table 10. Owing to this, the interchangeable units 4 or 30 are not contact with one another. As a result, even if these interchangeable units 4 or 30 thermally expand during film deposition treatment, the individual heat interchangeable units 4 or 30 can absorb dimensional changes caused by the thermal expansion, and do not affect the rotation and revolution of the workpieces W1 or W2.

(2)

In the film deposition system 1 of this embodiment, the lengths of the first arm 21 and the second arm 31 that are the support members supporting the first workpiece mount plates 22 and the second workpiece mount plates 32 are set such that on the line L1 extending through the rotation center O of the rotary table 10 and crossing at right angles the evaporation surface T1a of the target T1 from which particles are evaporated, the distance (S1) between the position W1a, where the workpiece W1 mounted on each first workpiece mount plate 22 faces the evaporation surface T1a, and the evaporation surface T1a becomes equal to the distance (S1) between the position W2a of the workpiece W2 mounted on each second workpiece mount plate 32, the position W2a facing the evaporation surface T1a, and the evaporation surface T1a. It is, therefore, possible to keep constant the distance between the target T1 and each of the workpieces W1 and W2 of the different sizes.

(3)

In the film deposition system 1 of this embodiment, the target T1 is held on the target holding portion 2e on the radially outer side of the rotary table 10. With this configuration, the distance from the rotation center O of the rotary table 10 to the target T1 is constant. Therefore, by setting the radius (R1 in FIG. 1) of the circumscribed circle C1a, with which the plural workpieces W1 mounted on the respective plural first workpiece mount plates 22 arranged side by side in the circumferential direction of the rotary table 10 are in contact, because equal to the radius (R1 in FIG. 4) of the circumscribed circle C1b, with which the plural workpieces W2 mounted on the respective plural second workpiece mount plates arranged side by side in the circumferential direction of the rotary table 10 are in contact, the distances obtained each by subtracting the radius R1 of each of these circumscribed circles C1a, C1b between the distance from the rotation center O of the rotary table 10 and the target T1, that is, the distances between the target T1 and the workpieces W1, W2 mounted on the respective workpiece mount plates 22, 32 of the first interchangeable units 4 and the second interchangeable units 30 become equally S1 and become constant, in other words, equal.

(4)

In the film deposition system 1 of this embodiment, despite the difference in number between the first interchangeable units 4 and the second interchangeable units 40, the first or second interchangeable units 4 or 30 can be arranged easily at equal intervals such that they are arranged side by side in the circumferential direction of the rotary table 10 by attaching the first interchangeable units 4 or the second interchangeable units 30 to the corresponding first attachment portions (that is, through-holes 10a, 10b) or the second attachment portions (that is, through-holes 10b, 10c) of the rotary table 10, respectively.

(5)

In the film deposition system 1 of this embodiment, the plural first attachment portions (that is, through-holes 10a, 10b) and the plural second attachment portions (that is, through-holes 10b, 10c) use the through-holes 10b in common. It is, therefore, possible to decrease the total number of the first attachment portions and the second attachment portions (that is, the total number of the through-holes 10a, 10b, 10c), and to improve the freedom of arrangement of the first attachment portions and the second attachment portions on the surface of the rotary table 10 and that of their peripheral members.

(6)

In the film deposition system 1 of this embodiment, if one type of replaceable units, that is, the first interchangeable units 4 or the second interchangeable units 30 are attached to the rotary table 10, the first or second workpiece mount plates 22 or 32 of these first or second interchangeable units 4 or 30 revolve around the rotation center O of the rotary table 10 while being supported by the first or second arms 21 or 31. In addition, the first or second planetary gears 23 or 33 rotate about the axes thereof in meshing engagement with the fixed gear 9, whereby the first or second workpiece mount plates 22 or 32 rotate about the axes thereof. Using the drive force that rotates the rotary table 10, the first or second workpiece mount plates 22 or 32 can rotate on the axes thereof.

(7)

In the film deposition system 1 of this embodiment, the diameter D1 of the first workpiece mount plates 22 in the first interchangeable unit 4 differs from the diameter D2 of the second workpiece mount plates 32 in the second interchangeable unit 30. With this configuration, the distance X1 (see FIG. 2) between the rotation center P1 of the first workpiece mount plate 22 and the first planetary gear 23 coaxially coupled to the first workpiece mount plate 22 and the teeth of the fixed gear 9 differs from the distance X2 (see FIG. 5) between the rotation center P2 of the second workpiece mount plate 32 and the second planetary gear 33 coaxially coupled to the second workpiece mount plate 32 and the teeth of the fixed gear 9. Therefore, by setting the diameters D11, D12 of the first planetary gear 23 and the second planetary gear 33 based on the diameters D1, D2 of the first workpiece mount plate 22 and the second workpiece mount plate 32, respectively, as described, it is possible to set the first planetary gear 23 and the second planetary gear 33 in such dimensions that they can be surely brought into meshing engagement with the fixed gear 9 even if the distances X1, X2 between the rotation centers O and the teeth 9a of the fixed gear 9 differ as described above.

### (Modifications)

### (A)

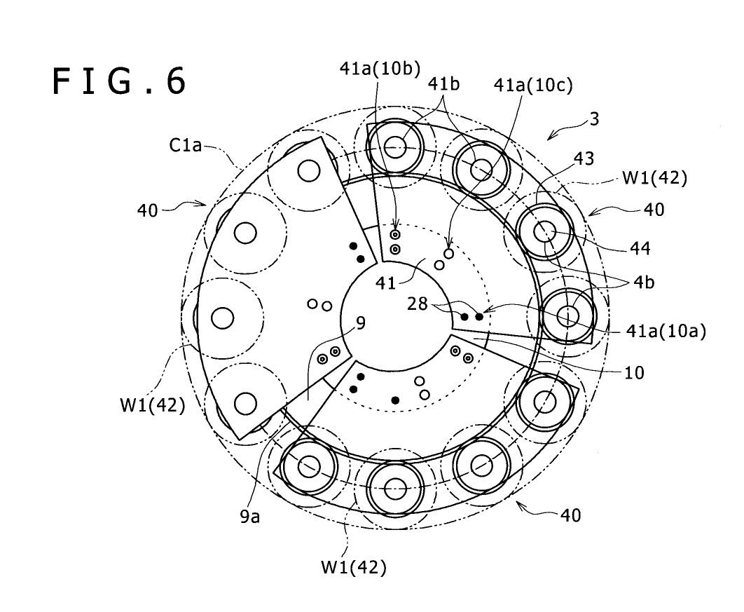

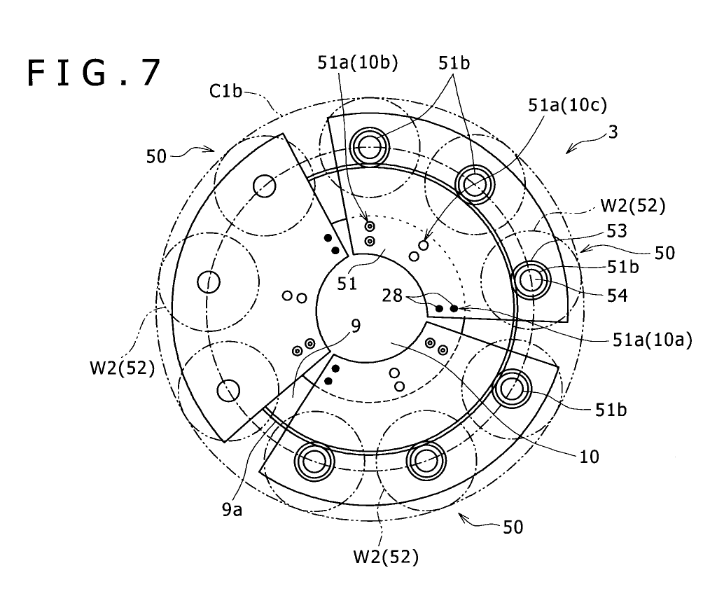

While the embodiment described above shows the configuration in which the first interchangeable unit 4 and the second interchangeable unit 30 each include one workpiece mount plate, one planetary gear, and one arm, the present invention is not limited to this configuration. As shown in FIGS. 6 and 7, the present invention may adopt a configuration in which plural workpiece mount plates and plural planetary gears are attached together to one attachment plate.

Described specifically, a rotary table unit 3 shown in FIG. 6 includes three first interchangeable units 40 for mounting 12 workpieces W1.

Each first interchangeable unit 40 includes four first workpiece mount plates 42 each for mounting thereon the workpiece W1; four first planetary gears 43; rotational shafts 44 integrally coupling these first workpiece mount plates 42 and planetary gears 43, respectively; and one first attachment plate 41 as a first support member that rotatably supports the rotational shafts 44.

The first planetary gears 43 are coaxially coupled to the first workpiece mount plates 42 by the rotational shafts 44, respectively. The first planetary gears 43 rotate about axes thereof in meshing engagement with the fixed gear 9.

The first attachment plate 41 is a sectorial flat member. Through-holes 41a are formed in an arcuate inner edge portion of the first attachment plate 41 such that they are arranged at plural locations and separately from one another in the circumferential direction of the rotary table 10. The through-holes 41a are superimposed on the through-holes 10a, 10b, 10c of the rotary table 10 and bolts 28 are inserted into these through-holes 41a and through-holes 10a to 10c. By fastening nuts 29 (see FIG. 2) to the ends of the bolts 28, the first interchangeable units 40 are detachably attached to the rotary table 10.

Through-holes 41b are formed in an arcuate outer edge portion of the first attachment plate 41. The rotational shafts 44 that couples the first workpiece mount plates 42 to the first planetary gears 43, respectively, extend through the respective through-holes 41b. Each rotational shaft 44 is rotatably supported by a rotation support member (not shown) including bearings provided around the associated through-hole 41b of the first attachment plate 41.

As shown in FIG. 7, a table unit 3 includes, similarly to the first interchangeable units 40 dedicated to the workpieces W1 shown in FIG. 6, three second interchangeable units 50 for mounting nine workpieces W2 of the larger diameter than that of the workpieces W1.

Each second interchangeable unit 50 includes three second workpiece mount plates 52 each for mounting thereon the workpiece W2; three first planetary gears 53; rotational shafts 54 integrally coupling these second workpiece mount plates 52 and planetary gears 53, respectively; and one second attachment plate 51 as a second support member that rotatably supports the rotational shafts 54.

The second planetary gears 53 are coaxially coupled to the second workpiece mount plates 52 by the rotational shafts 54, respectively. The second planetary gears 53 rotate about axes thereof in meshing engagement with the fixed gear 9.

The second attachment plate 51 is a sectorial flat member. Through-holes 51a are formed in an arcuate inner edge portion of the second attachment plate 51 such that they are arranged at plural locations and apart from one another in the circumferential direction of the rotary table 10. The through-holes 51a are superimposed on the through-holes 10a, 10b, 10c of the rotary table 10 and the bolts 28 are inserted into these through-holes 51a and through-holes 10a to 10c. By fastening nuts 29 to the ends of the bolts 28, the second interchangeable units 50 are detachably attached to the rotary table 10.

Through-holes 51b are formed in an arcuate outer edge portion of the second attachment plate 51. The rotational shafts 54 that couple the second workpiece mount plates 52 to the second planetary gears 53, respectively, extend through the respective through-holes 51b. Each rotational shaft 54 is rotatably supported by a rotation support member (not shown) including bearings provided around the associated through-hole 51b of the second attachment plate 51.

One type of interchangeable units, that is either the first interchangeable units 40 or the second interchangeable units 50 configured as described above can be selected and attached to the rotary table 10.

In the modifications shown in FIGS. 6 and 7, the first interchangeable units 40 and the second interchangeable units 50 each includes the attachment plate 41 or 51 that includes the plural rotation support members (not shown) rotatably supporting the plural workpiece mount plates 42 or 52 and the plural planetary gears 43 or 53. Owing to this, the number of interchangeable units 40 and 50 can be decreased while securing the workpiece mount plates 42 and 52 as many as needed. This can reduce the man-hours of work for the attachment and detachment of the interchangeable units 40 and 50 and can facilitate the management of the interchangeable units 40 and 50.

### (B)

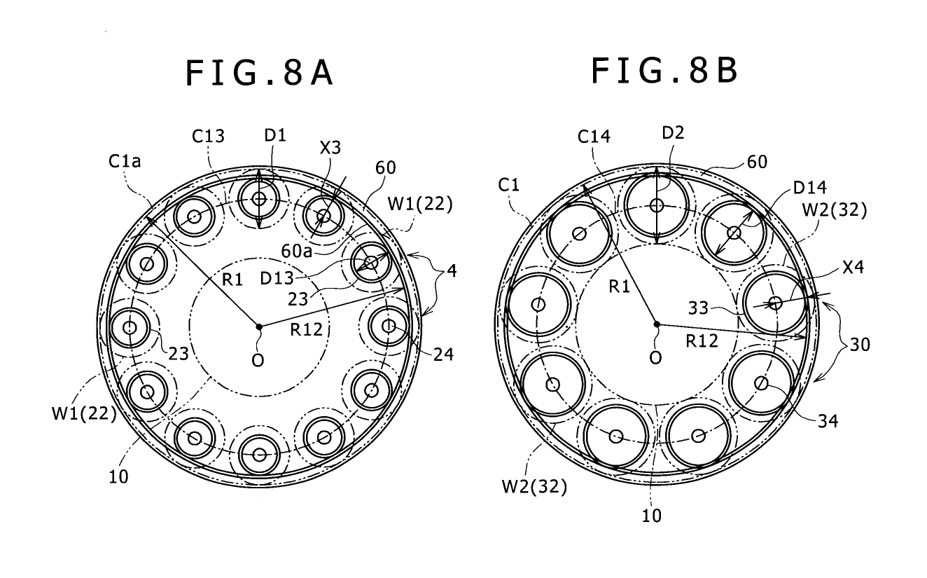

While the above embodiment is described taking an external gear as the fixed gear 9, the present invention is not limited to this. As shown in FIGS. 8A and 8B, an internal gear having teeth 60a formed on an inner circumference may be adopted as a fixed gear 60.

In this case, if the first interchangeable units 4 are attached to the rotary table 10, the first planetary gears 23 arranged coaxially with the first workpiece mount plates 22 each mounting thereon the workpiece W1 are arranged on a side of an inner circumference of the fixed gear 60 and is kept in meshing engagement with the teeth 60a protruding inwardly as shown in FIG. 8A. Likewise, if the second interchangeable units 30 are attached to the rotary table 10, the second planetary gears 33 arranged coaxially with the second workpiece mount plates 32 each mounting thereon the workpiece W2 are arranged on the inner circumference of the fixed gear 60 and is kept in meshing engagement with the teeth 60a protruding inwardly as shown in FIG. 8B.

Therefore, the fixed gear 60 is located on a side outer than the first planetary gears 23 or the second planetary gears 33 in the radial direction of the rotary table 10 and is kept in meshing engagement with the first planetary gears 23 or the second planetary gears 33.

If the fixed gear 60 constituted by the internal gear having the teeth 60a on the inner circumference thereof is used as described above, the fixed gear 60 can be arranged outwardly apart from the rotary table 10 in the radial direction of the rotary table 10 and the space around the rotation center O of the rotary table 10 can be secured since the fixed gear 60 is located on a side outer than of the first planetary gears 23 or the second planetary gears 32 in the radial direction of the rotary table 10. This can facilitate the designing and manufacture of the rotary table unit 3.

With the configuration of using the fixed gear 60 constituted by the internal gear as described in this modification (B), a diameter D13 of the first planetary gears 23 coaxially coupled to the first workpiece mount plates 22 in the respective first interchangeable units 4 shown in FIG. 8A can be determined based on the diameter D1 of the first workpiece mount plates 22 as represented by the following Equation (5).

D13=2×X3=2×(R12−(R1−(D1/2)))=2×(R12−R1+(D1/2)) (5)

where,
X3: distance between a virtual circle C13 connecting centers of the rotary shafts 24 and the fixed gear 60;

R1: radius of the circumscribed circle C1a of the workpieces W1; and

R12: radius of the fixed gear 60.

Likewise, a diameter D14 of the second planetary gears 33 coaxially coupled to the second workpiece mount plates 32 in the respective second interchangeable units 30 shown in FIG. 8B can be determined based on the diameter D2 of the second workpiece mount plates 32 as represented by the following Equation (6).

D14=2×X4=2×(R12−(R1−(D2/2)))=2×(R12−R1+(D2/2)) (6)

### (C)

In the film deposition system 1 of this embodiment, there is shown the configuration that the target T1 is held on the target holding portion 2e on the radially outer side of the rotary table 10. The present invention is, however, not limited to this configuration. The target may be arranged on a radially inner side of the rotary table 10.

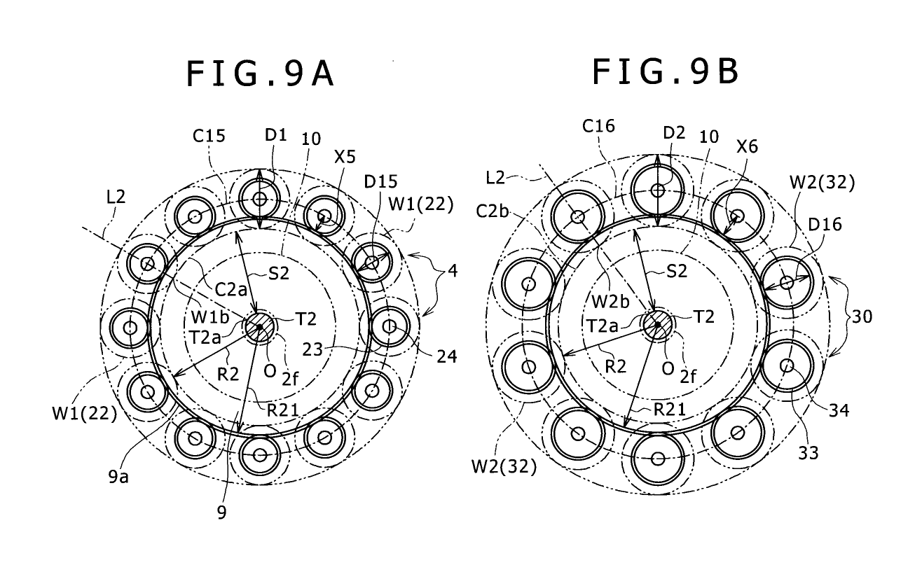

In this case, as shown in FIGS. 9A and 9B, a target holding portion 2f is arranged on the central axis O of the rotary table 10. The target holding portion 2f is arranged, for example, below the top wall of the chamber 2. On the target holding portion 2f, a cylindrical target T2 is arranged at a position upwardly apart from the rotary table 10 in a state that it is suspended along the central axis O.

When the target T2 is arranged on the central axis O of the rotary table 10 as described above, the distance between each of the workpieces W1, W2 and the target T2 can be kept constant irrespective of an interchange of the workpieces and the interchangeable units, if, as shown in FIG. 9A, a radius (R2 in FIG. 9A) of an inscribed circle C2a, with which the plural workpieces W1 mounted on the respective first workpiece mount plates 22 arranged side by side in the circumferential direction of the rotary table 10 are in contact, respectively, on a radially inner side of the rotary table 10 is set equal to a radius (R2 in FIG. 9B) of an inscribed circle C2b, with which the plural workpieces W2 having a diameter greater than the workpieces W1 and mounted on the respective second workpiece mount plates 32 arranged side by side in the circumferential direction of the rotary table 10 are in contact, respectively, on the inner side of the rotary table 10.

That is, with such a configuration, the distance from the rotation center O of the rotary table 10 to an evaporation surface T2a of the target T2 is constant. By setting the radii of these inscribed circles C2a and C2b equally at R2, the distances obtained each by subtracting the distance between the rotation center O of the rotary table 10 and the evaporation surface T2a of the target T2 from the radius R2 of each of these inscribed circles C2a and C2b, that is, the distances between the target T2 held in the target holding portion 2f on the radially inner side of the rotary table 10 and the workpieces W1, W2 mounted on the workpiece mount plates 22, 32 of the respective first interchangeable units 4 and the second interchangeable units 30 become equally S2 and constant.

With the configuration in which the target T2 is arranged on the rotation center O on the radially inner side of the rotary table 10 as described in this modification (C), a diameter D15 of the first planetary gears 23 coaxially coupled to the first workpiece mount plates 22 in the respective first interchangeable units 4 shown in FIG. 9A can be determined based on the diameter D1 of the first workpiece mount plates 22 as represented by the following Equation (7).

D15=2×X5=2×(R2+(D1/2)−R21) (7)

### Where:

X5: distance between a virtual circle C15 connecting the centers of the rotary shafts 24 and the fixed gear 9;

R2: radius of the circumscribed circle C2a of the workpieces W1; and

R21: radius of the fixed gear 9.

Likewise, a diameter D16 of the second planetary gears 33 coaxially coupled to the second workpiece mount plates 32 in the respective second interchangeable units 30 shown in FIG. 9B can be determined based on the diameter D2 of the second workpiece mount plates 32 as represented by the following Equation (8).

D16=2×X6=2×(R2+(D2/2)−R21) (8)

### (D)

In the above-described embodiment, the combination of the through-holes 10a and 10b and the combination of the through-holes 10b and 10c are described by way of example as the first attachment portions and the second attachment portions for attaching the first and second interchangeable units 4, 30 to the rotary table 10. However, the present invention is not limited to this configuration. First attachment portions and second attachment portions of other configurations may be adopted insofar as they are of detachable configurations.

### (E)

In the above-described embodiment, the rotary table 10 is described by way of example as an example of the rotor to which the first and second interchangeable units 4 and 30 are detachably attached. However, the present invention is not limited to the rotary table 10. Rotors of various shapes and structures may be adopted insofar as they can rotate about axes thereof with the first or second interchangeable units 4 or 30 attached to the rotors.

### (F)

While the embodiment is described taking the two types of the interchangeable units 4, 30 as examples, the present invention is not limited to these types. The film deposition system may be configured to include three or more types of interchangeable units.

### (G)

While the line L1 which crosses at right angles the evaporation surface T1a of the target T1 (see FIG. 1) extends through the rotation center O in the above-described embodiment, the present invention is not limited to this configuration. A positional relation that the line L1 does not extend through the rotation center O may be adopted.

### (H)

While the embodiment is described by taking, as an example, the state in which only one type of interchangeable units, that is, either the first interchangeable units 4 or the second interchangeable units 30 are attached to the rotor, the present invention is not limited to such a state. Some of the first interchangeable units 4 and some of the second interchangeable units 30 may be attached in combination to the rotor.

What is claimed is:

1. A film deposition system for subjecting workpieces to film deposition treatment with particles evaporated from a target, comprising:
a chamber with the target placed therein, and
a rotor unit accommodated in the chamber;
wherein the rotor unit comprises:
a rotor;
a drive unit for driving the rotor to rotate about a rotation center and
plural interchangeable units including workpiece mount plates for mounting thereon the workpieces, respectively, and support members rotatably supporting the workpiece mount plates, respectively, the plural interchangeable units being detachably attachable to the rotor such that the interchangeable units are arranged apart from one another and side by side at intervals in a circumferential direction of the rotor.

2. The film deposition system according to claim 1, wherein:
the interchangeable units include:
plural first interchangeable units including first workpiece mount plates for mounting thereon plural workpieces of a first diameter, respectively, and first support members rotatably supporting the first workpiece mount plates, respectively, the plural first interchangeable units being detachably attachable to the rotor such that the first interchangeable units are arranged apart from one another and side by side at intervals in the circumferential direction of the rotor, and
plural second interchangeable units including second workpiece mount plates for mounting thereon plural workpieces of a second diameter larger than the first diameter, respectively, and second support members rotatably supporting the second workpiece mount plates, respectively, the plural second interchangeable units being detachably attachable to the rotor such that the second interchangeable units are arranged apart from one another and side by side at intervals in the circumferential direction of the rotor, and
at least one type of interchangeable units selected from the group consisting of the first interchangeable units and the second interchangeable units are selectable for attachment to the rotor.

3. The film deposition system according to claim 2, wherein a distance between a position, where the workpiece mounted on each first workpiece mount plate faces an evaporation surface of the target from which the particles are evaporated, and the rotation center of the rotor is set equal to a distance between a position, where of the workpiece mounted on each second workpiece mount plate faces the evaporation surface, and the rotation center of the rotor.

4. The film deposition system according to claim 3, wherein:
the target is arranged on a radially outer side of the rotor, and
a radius of a circumscribed circle, with which the plural workpieces mounted, respectively, on the plural first workpiece mount plates arranged side by side in the circumferential direction of the rotor, are in contact, respectively, on the radially outer side of the rotor of the rotor is set equal to a radius of a circumscribed circle, with which the plural workpieces mounted, respectively, on the plural second workpiece mount plates arranged side by side in the circumferential direction of the rotor, are in contact, respectively, on the radially outer side of the rotor.

5. The film deposition system according to claim 3, wherein:
the target is arranged on a central axis of the rotor, and
a radius of an inscribed circle, with which the plural workpieces mounted, respectively, on the plural first workpiece mount plates arranged side by side in the circumferential direction of the rotor, are in contact, respectively, on a radially inner side of the rotor, is set equal to a radius of an inscribed circle, with which the plural workpieces mounted, respectively, on the plural second workpiece mount plates arranged side by side in the circumferential direction of the rotor, are in contact, respectively, on the radially inner side of the rotor.

6. The film deposition system according to claim 2, wherein:
the rotor includes:
plural first attachment portions to which the first interchangeable units are attachable; and
plural second attachment portions to which the second interchangeable units are attachable,
the plural first attachment portions are included as many as a maximum attachable number of the first interchangeable units, and are disposed at equal intervals such that the plural first attachment portions are arranged side by side in the circumferential direction of the rotor, and
the plural second attachment portions are included as many as a maximum attachable number of the second interchangeable units, and are disposed at equal intervals such that the plural second attachment portions are arranged side by side in the circumferential direction of the rotor.

7. The film deposition system according to claim 6, wherein the plural first attachment portions and the plural second attachment portions are partly in with each other.

8. The film deposition system according to claim 2, wherein:
the rotor unit further includes:
a base that rotatably supports the rotor, and
a fixed gear fixed on the base;
the first interchangeable units each further include a first planetary gear, which is coaxially coupled to the first workpiece mount plate and is rotatable about an axis thereof in meshing engagement with the fixed gear;
the second interchangeable units each further include a second planetary gear, which is coaxially coupled to the second workpiece mount plate and is rotatable about an axis thereof in meshing engagement with the fixed gear;
each first support member is a first arm that includes a rotation support member rotatably supporting the first workpiece mount plate and the first planetary gear thereon and a first couple portion detachably coupled to the rotor, and that revolves, together with the rotor, around the rotation center; and
each second support member is a second arm that includes a rotation support member rotatably supporting the second workpiece mount plate and the second planetary gear thereon and a second couple portion detachably coupled to the rotor, and that revolves, together with the rotor, around the rotation center.

9. The film deposition system according to claim 2, wherein:
the rotor unit further includes:
a base that rotatably supports the rotor, and
a fixed gear fixed on the base;
the first interchangeable units further include plural first workpiece mount plates and plural first planetary gears that are coaxially coupled to the plural first workpiece mount plates, respectively, and that are rotatable about axes thereof in meshing engagement with the fixed gear;
the second interchangeable units further include plural second workpiece mount plates and plural second planetary gears that are coaxially coupled to the plural second workpiece mount plates, respectively, and that are rotatable about axes thereof in meshing engagement with the fixed gear;
the first support members are first attachment plates that include plural rotation support members rotatably supporting the plural first workpiece mount plates and the plural first planetary gears thereon and first couple portions coupled to the rotor, and that revolve, together with the rotor, around the rotation center, and
the second support members are second attachment plates that include plural rotation support members rotatably supporting the plural second workpiece mount plates and the plural second planetary gears thereon and second couple portions coupled to the rotor, and that revolves, together with the rotor, around the rotation center.

10. The film deposition system according to claim 8, wherein:
the fixed gear is an internal gear having teeth on a side of an inner circumference thereof, and
the fixed gear is located on a side radially outer than the first planetary gears and the second planetary gears, and is in meshing engagement with the first planetary gears and the second planetary gears.

11. The film deposition system according to claim 8, wherein:
diameters of the first planetary gears and the second planetary gears are set based on diameters of the first workpiece mount plates and the second workpiece mount plates, respectively.
